(19) United States
(12) Patent Application Publication
(10) Pub. No.: US 2025/0024656 A1
(43) Pub. Date: Jan. 16, 2025

(54) PRESSING MECHANISM AND DISPLAY DEVICE

(71) Applicant: HKC CORPORATION LIMITED, Shenzhen (CN)

(72) Inventors: HONGSONG WANG, Shenzhen (CN); Lidan Ye, Shenzhen (CN)

(21) Appl. No.: 18/672,040

(22) Filed: May 23, 2024

(30) Foreign Application Priority Data
Jul. 11, 2023 (CN) 202310840852.0

(51) Int. Cl. H05K 13/00; H05K 1/14

(52) U.S. Cl. CPC H05K 13/0053; H05K 1/144; H05K 13/0015; H05K 13/0069; H05K 2201/10128

(57) ABSTRACT

A pressing mechanism and a display device are disclosed. The pressing mechanism includes a guide rail extending in a direction consistent with a width direction of a flexible cable, a positioning device connected to a side of the guide rail facing towards a printed circuit board, and a pressing device sleeved on the guide rail and operative to move along the guide rail and used to press a junction between the printed circuit board and the flexible cable. The positioning device includes a first and a second positioning piece respectively arranged on both sides of the pressing device. The second positioning piece is movably connected to the guide rail and is operative to move along the guide rail. The first and the second positioning piece are detachably connected to the printed circuit board, and respectively abut against both sides of the flexible cable in the width direction.

### CROSS-REFERENCE TO RELATED APPLICATIONS

This application claims the priority and benefit of Chinese patent application number 2023108408520, titled “Pressing Mechanism and Display Device” and filed Jul. 11, 2023 with China National Intellectual Property Administration, the entire contents of which are incorporated herein by reference.

### TECHNICAL FIELD

This application relates to the field of display technology, and more particularly relates to a pressing mechanism and a display device.

### BACKGROUND

The description provided in this section is intended for the mere purpose of providing background information related to the present application but doesn't necessarily constitute prior art.

A flexible cable is used to transmit current signals between a display panel and a printed circuit board. A pressing mechanism may be used to press both ends of the flexible cable on the display panel and the printed circuit board respectively thus creating a stable connection between the flexible cable and the printed circuit board.

The pressing mechanism currently used may be a connector. The connector may be installed on the printed circuit board, and the flexible cable may be inserted into an end socket of the connector to create a junction between the flexible cable and the printed circuit board. However, since the connector has a certain fixed specification, it can only be connected with a matching flexible cable after being installed on the printed circuit board. Furthermore, after multiple closures, the connector may be loosened, causing the connection of the flexible cable to become unstable thereby leading to emergencies.

Therefore, how to adjust the pressing range of the pressing mechanism depending on the junction between the flexible cable of different specifications and the printed circuit board thus improving the applicability of the pressing mechanism has become an urgent problem that needs to be solved in this field.

### SUMMARY

This application discloses a pressing mechanism and a display device. One purpose is to adjust the pressing range of the pressing mechanism depending on the flexible cables of different specifications, so as to achieve a stable connection between the flexible cable and the printed circuit board thus improving the applicability of the pressing mechanism.

This application discloses a pressing mechanism. The pressing mechanism includes a positioning device, a pressing device, and a guide rail. The positioning device is connected to a side of the guide rail facing towards a printed circuit board. A direction of extension of the guide rail is consistent with a width direction of a flexible cable. The pressing device is sleeved on the guide rail and is operative to move along the direction of extension of the guide rail and is used for pressing a junction between the printed circuit board and the flexible cable. The positioning device includes a first positioning piece and a second positioning piece, which are respectively arranged on both sides of the pressing device. The second positioning piece is movably connected to the guide rail and is operative to move along the direction of extension of the guide rail. The first positioning piece and the second positioning piece are detachably connected to the printed circuit board and respectively abut against both sides of the flexible cable in the width direction.

In some embodiments, the guide rail includes at least two guide rail splicing pieces, which are spliced end to end to form the guide rail.

In some embodiments, the guide rail includes a first guide rail and a second guide rail. The first guide rail is connected to a top of the first positioning piece and a top of the second positioning piece. The second guide rail is disposed below the first guide rail, and there is defined a gap between the first guide rail and the second guide rail. The pressing device is sleeved on the first guide rail. One end of the second guide rail is connected to a side of the first positioning piece facing towards the pressing device, and the other end passes through the second positioning piece and is movably connected with the second positioning piece.

In some embodiments, the pressing device includes a pressing head assembly and a base. The base is sleeved on the guide rail. A storage cavity is defined in a side of the base facing towards the printed circuit board, and there is disposed in the storage cavity a first motor and a second motor that are spaced apart in a horizontal direction. The pressing head assembly includes a pressing head, a pressing head rod, and a limiting sleeve. One end of the pressing head rod passes through the limiting sleeve, is connected to the pressing head, and is partially exposed from the limiting sleeve. A side of the limiting sleeve facing away from the base is connected to the pressing head. The pressing head rod is arranged between the first motor and the second motor. The first motor includes a first electric gear, and the second electric motor includes a second electric gear. The part of the pressing head rod that is exposed from the limiting sleeve includes a plurality of rack teeth on side walls respectively facing towards the first motor and the second motor, and the plurality of rack teeth are respectively connected to the first electric gear and the second electric gear. The first motor and the second motor are operative to rotate forward or reverse to control a rise or fall of the pressing head rod. A width of the limiting sleeve is greater than a distance between the first motor and the second motor. A height of the portion of the pressing head rod exposed from the limiting sleeve is equal to a thickness of the flexible cable.

In some embodiments, the pressing head includes a main pressing head splicing piece, a first pressing head splicing piece, and a second pressing head splicing piece. The main pressing head splicing piece is connected to a side of the pressing head rod facing towards the printed circuit board. The first pressing head splicing piece and the second pressing head splicing piece are respectively arranged on both sides of the main pressing head splicing piece. The first pressing head splicing piece, the main pressing head splicing piece, and the second pressing head splicing piece are spliced end to end in order to form the pressing head. The first pressing head splicing piece and the second pressing head splicing piece each include a connecting piece on a side facing towards the guide rail. The pressing head assembly further includes at least a first support rod and a second support rod. One end of the first support rod and one end of the second support rod are movably connected to both sides of the limiting sleeve respectively. The other end of the first support rod is movably connected to the connecting piece of the first pressing head splicing piece. The other end of the second support rod is movably connected to the connecting piece of the second pressing head splicing piece.

In some embodiments, the first positioning piece and the second positioning piece each include one or more suction cups on a side facing towards the printed circuit board, and the first positioning piece and the second positioning piece are suction-connected to the printed circuit board through the one or more suction cups.

In some embodiments, the first positioning piece includes a first pre-pressing piece on a side facing towards the pressing head, and the second positioning piece includes a second pre-pressing piece on one side facing towards the pressing head. The second pre-pressing piece and the first pre-pressing piece each include a support block, an elastic piece, and a pre-pressing block. A limiting groove is defined in a side of the support block facing towards the pressing head, and the direction of extension of the limiting groove is the direction in which the pressing head points toward the printed circuit board. One end of the elastic piece is connected to a side of a top of the support block facing towards the printed circuit board, and the other end is connected to the pre-pressing block. The pre-pressing block is partially embedded in the limiting groove and is operative to move along the direction of extension of the limiting groove. The support block of the first pre-pressing piece and the support block of the second pre-pressing piece respectively abut against both sides of the flexible cable in the width direction. In a natural state of each pre-pressing block, a distance between a bottom surface of the pre-pressing block and a bottom surface of the support block is less than a thickness of the flexible cable. The distance between the support block and the printed circuit board is greater than a half a height of each suction cup and less than or equal to the height of each suction cup.

In some embodiments, the pressing mechanism further includes a first support piece and a second support piece, which are respectively connected to both sides of the guide rail. The distance between bottom surfaces of the first support piece and the second support piece and the printed circuit board is greater than a half the height of each suction cup.

In some embodiments, there is disposed a buffer layer on a side of the pressing head facing towards the printed circuit board, where the buffer layer is made of a plastic composite material.

This application further discloses a display device, including a display panel. The display device further includes the above-mentioned pressing mechanism, a printed circuit board, and a flexible cable. The printed circuit board is connected to the display panel through the flexible cable. The pressing mechanism is disposed on the printed circuit board and is used to press the junction between the flexible cable and the printed circuit board.

The pressing mechanism of the present application uses the pressing device to press the junction between the printed circuit board and the flexible cable, so that the flexible cable and the printed circuit board can be stably connected and not easy to fall apart, thus maintaining good signal transmission. In particular, the first positioning piece and the second positioning piece are used to press horizontally from both sides in a width of the flexible cable so that the flexible cable can be accurately positioned at the connection position with the printed circuit board and is not prone to positional deviation, thereby further improving the stability of the junction between the flexible cable and the printed circuit board. Both the pressing device and the second positioning piece in this application can move along the guide rail, so that the positions of the pressing device and the second positioning piece can be adjusted to adjust the pressing range of the pressing mechanism depending on the width of the flexible cable of different specifications, and so the first positioning piece and the second positioning piece can press against the flexible cable of different widths. Furthermore, the pressing device can be accurately aligned with the junction between the flexible cable of different widths and the printed circuit board, and press the junction, so that the flexible cable and the printed circuit board can be stably connected together, ensuring signal transmission and improving the applicability of the pressing mechanism.

### BRIEF DESCRIPTION OF DRAWINGS

The accompanying drawings are used to provide a further understanding of the embodiments according to the present application, and constitute a part of the specification. They are used to illustrate the embodiments according to the present application, and explain the principle of the present application in conjunction with the text description. Apparently, the drawings in the following description merely represent some embodiments of the present disclosure, and for those having ordinary skill in the art, other drawings may also be obtained based on these drawings without investing creative. In the drawings:

FIG. 1 is a schematic diagram of a first embodiment of a pressing mechanism according to the present application.

FIG. 2 is a schematic diagram of a guide rail in a second embodiment of the pressing mechanism according to the present application.

FIG. 3 is a schematic diagram of a third embodiment of the pressing mechanism according to the present application.

FIG. 4 is a schematic diagram of a fourth embodiment of the pressing mechanism according to the present application.

FIG. 5 is a schematic diagram of a fifth embodiment of the pressing mechanism according to the present application.

FIG. 6 is a schematic diagram of a sixth embodiment of the pressing mechanism according to the present application.

FIG. 7 is a schematic diagram of a seventh embodiment of the pressing mechanism according to the present application.

FIG. 8 is a schematic diagram of an embodiment of a display device according to the present application.

In the drawings: 10. Display device; 100. Pressing mechanism; 200. Display panel; 300. Printed circuit board; 400. Flexible cable; 110. Positioning device; 111. First positioning piece; 112. Second positioning piece; 113. Suction cup; 114. First pre-pressing piece; 115. Second pre-pressing piece; 116. Support block; 117. Limiting groove; 118. Elastic piece; 119. Pre-pressing block; 120. Pressing device; 121. Pressing head assembly; 122. Pressing head; 123. Main pressing head splicing piece; 124. First pressing head splicing piece; 125. Second pressing head splicing piece; 126. Buffer layer; 142. Connecting piece; 127. Pressing head rod; 128. Rack teeth; 129. Limiting sleeve; 130. First support rod; 131. Second support rod; 140. Base; 141. Storage cavity; 150. First motor; 151. First electric gear; 160. Second motor; 161. Second electric gear; 170. Guide rail; 171. Guide rail splicing piece; 172. First guide rail; 173. Second guide rail; 180. First support piece; 190. Second support piece; 191. Fixing sleeve.

### DETAILED DESCRIPTION OF EMBODIMENTS

The present application will be described in detail below with reference to the accompanying drawings and optional embodiments. It should be noted that, should no conflict is present, the various embodiments or technical features described below can be combined arbitrarily to obtain new embodiments.

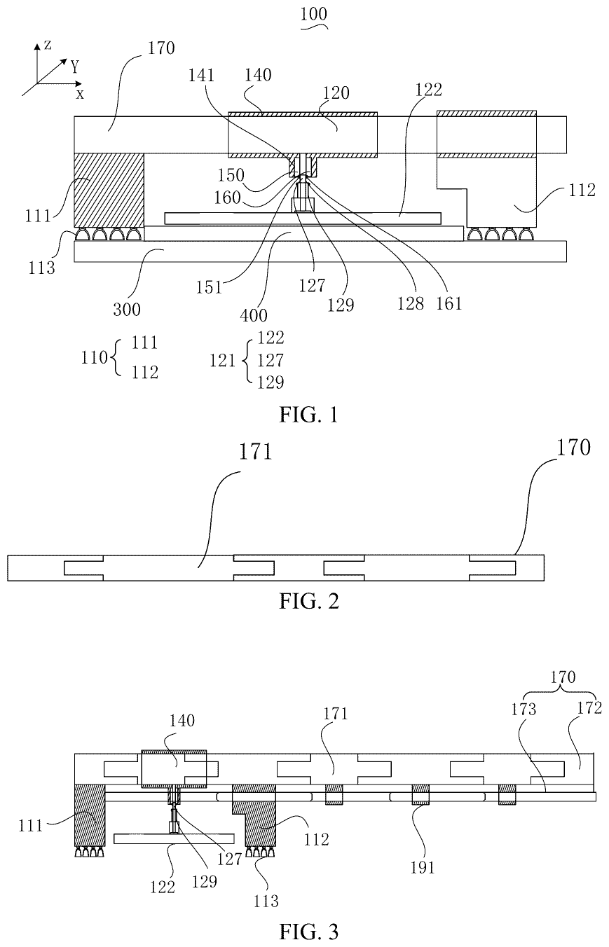

FIG. 1 is a schematic diagram of a first embodiment of a pressing mechanism according to the present application. As shown in FIG. 1, this application discloses a pressing mechanism 100. The pressing mechanism 100 includes a positioning device 110, a pressing device 120, and a guide rail 170. The positioning device 110 is connected to a side of the guide rail 170 facing towards the printed circuit board 300. The guide rail 170 extends in a direction that is consistent with a width direction of the flexible cable 400. The pressing device 120 is sleeved on the guide rail 170 and is able to move along the direction of extension of the guide rail 170 for pressing the junction between the printed circuit board 300 and the flexible cable 400. The positioning device 110 includes a first positioning piece 111 and a second positioning piece 112. The first positioning piece 111 and the second positioning piece 112 are respectively disposed on both sides of the pressing device 120. The second positioning piece 112 is movably connected to the guide rail 170 and is able to move along the direction of extension of the guide rail 170. The first positioning piece 111 and the second positioning piece 112 are detachably connected to the printed circuit board 300 and respectively abut against both sides of the flexible cable 400 in the width direction.

The pressing mechanism 100 of the present application uses the pressing device 120 to vertically press the junction between the printed circuit board 300 and the flexible cable 400, so that the flexible cable 400 and the printed circuit board 300 can be stably connected and not easy to fall apart, thus maintaining good signal transmission. In particular, the first positioning piece 111 and the second positioning piece 112 are used to press horizontally from both sides in a width of the flexible cable 400 so that the flexible cable 400 can be accurately positioned at the connection position with the printed circuit board 300 and is not prone to positional deviation, thereby further improving the stability of the junction between the flexible cable 400 and the printed circuit board 300. Both the pressing device 120 and the second positioning piece 112 in this application can move along the guide rail 170, so that the positions of the pressing device 120 and the second positioning piece 112 can be adjusted to adjust the pressing range of the pressing mechanism 100 depending on the width of the flexible cable 400 of different specifications, and so the first positioning piece 111 and the second positioning piece 112 can press against the flexible cable 400 of different widths from the horizontal X-axis direction. Furthermore, the pressing device 120 can be accurately aligned with the junction between the flexible cable 400 of different widths and the printed circuit board 300, and press the connection in the vertical Z-axis direction, so that the flexible cable 400 and the printed circuit board 300 can be stably connected together, ensuring signal transmission and improving the applicability of the pressing mechanism 100.

In particular, suction cups 113 may be disposed on the sides of the first positioning piece 111 and the second positioning piece 112 facing towards the printed circuit board 300. The first positioning piece 111 and the second positioning piece 112 are suction-connected to the printed circuit board 300 through the suction cups 113.

In the process of actually using the pressing mechanism 100 to press the junction between the flexible cable 400 and the printed circuit board 300, the pressing mechanism 100 is first aligned with the junction between the flexible cable 400 and the printed circuit board 300, and the first positioning piece 111 and the second positioning piece 112 are placed on the printed circuit board 300, and further the flexible cable 400 is placed between the first positioning piece 111 and the second positioning piece 112. Then depending on the width of the flexible cable 400, the position of the second positioning piece 112 on the guide rail 170 is adjusted so that the first positioning piece 111 and the second positioning piece 112 can just press against both sides of the flexible cable 400 in the width direction, achieving positioning of the flexible cable 400 in the horizontal X-axis direction. Then, the entire pressing mechanism 100 is pressed down. At this time, the suction cups 113 disposed on the sides of the first positioning piece 111 and the second positioning piece 112 facing towards the printed circuit board 300 are pressed, so that a negative pressure suction connection is created between the suction cups 113 and the printed circuit board 300. In this way, the first positioning piece 111 and the second positioning piece 112 can be fixed to the printed circuit board 300, further enhancing the stability of the junction between the pressing mechanism 100 and the printed circuit board 300, so that the pressing mechanism 100 is not easily detached from the printed circuit board 300.

Further, the pressing device 120 includes a pressing head assembly 121 and a base 140. The base 140 is sleeved on the guide rail 170. A storage cavity 141 is defined in the side of the base 140 facing towards the printed circuit board 300. The storage cavity 141 contains a first motor 150 and a second motor 160 spaced apart along the horizontal direction. The pressing head assembly 121 includes a pressing head 122, a pressing head rod 127, and a limiting sleeve 129. One end of the pressing head rod 127 passes through the limiting sleeve 129, is connected to the pressing head 122, and is partially exposed from the limiting sleeve 129. The side of the limiting sleeve 129 facing away from the base 140 is connected to the pressing head 122. The pressing head rod 127 is disposed between the first motor 150 and the second motor 160. The first motor 150 includes a first electric gear 151. The second motor 160 includes a second electric gear 161. The part of the pressing head rod 127 that exposes the limiting sleeve 129 includes a plurality of rack teeth 128 on the side walls facing towards the first motor 150 and the second motor 160. The plurality of rack teeth 128 are respectively connected to the first electric gear 151 and the second electric gear 161, and the first motor 150 and the second motor 160 rotate forward or reverse to control the rise or fall of the pressing head rod 127. The width of the limiting sleeve 129 is greater than the distance between the first motor 150 and the second motor 160. The height of the portion of the pressing head rod 127 exposed from the limiting sleeve 129 is equal to the thickness of the flexible cable 400.

After the position of the flexible cable 400 is limited in the horizontal X-axis direction through the first positioning piece 111 and the second positioning piece 112, the pressing device 120 can be used to press the flexible cable 400 in the vertical Z-axis direction. When the flexible cable 400 needs to be pressed, the first motor 150 and the second motor 160 may be controlled to rotate forward, so that a rotating shaft of the first motor 150 drives the first electric gear 151 to rotate, and a rotating shaft of the second motor 160 drives the second electric gear 161 to rotate. When the first electric gear 151 and the second electric gear 161 rotate simultaneously, the pressing head rod 127 is driven to move downward. At this time, the pressing head 122 connected to the side of the pressing head rod 127 facing towards the printed circuit board 300 moves downward together with the pressing head rod 127 until it abuts on the flexible cable 400 and presses the junction between the flexible cable 400 and the printed circuit board 300 so that the port pins of the flexible cable 400 and the pins of the printed circuit board 300 are connected to create stable signal conduction. When the flexible cable 400 needs to be replaced and removed from the printed circuit board 300, the first motor 150 and the second motor 160 may be controlled to rotate in reverse, so that the rotating shaft of the first motor 150 drives the first electric gear 151 to rotate in the reverse direction, the rotating shaft of the second motor 160 drives the second electric gear 161 to rotate in the reverse direction. When the first electric gear 151 and the second electric gear 161 rotate simultaneously, the pressing head rod 127 is driven to move upward. At this time, the pressing head 122 connected to the side of the pressing head rod 127 facing towards the printed circuit board 300 moves upward together with the pressing head rod 127 to release the pressing state of the flexible cable 400 until it leaves the flexible cable 400, so that the flexible cable 400 can be removed from the printed circuit board 300 for replacement.

Furthermore, since the width of the limiting sleeve 129 is greater than the distance between the first motor 150 and the second motor 160, the height of the portion of the pressing head rod 127 exposed from the limiting sleeve 129 is equal to the thickness of the flexible cable 400. The pressing head rod 127 has enough distance to be accommodated in the storage cavity 141 during the rising process, and the limiting sleeve 129 prevents the pressing head rod 127 from rising excessively driven by the first motor 150 and the second motor 160 and causing the pressing head rod 127 to impact the guide rail 170, leading to deformation or damage of the guide rail 170.

Furthermore, in order to enable the pressing mechanism 100 to press the flexible cables 400 of different width specifications, and further to adaptively adjust the space occupied by the pressing mechanism 100 to avoid unnecessary space occupation thereby enhancing the adaptability of the pressing mechanism 100, this application further improves the guide rail 170 of the pressing mechanism 100. The specific improvements are as follows.

FIG. 2 is a schematic diagram of a guide rail in a second embodiment of the pressing mechanism according to the present application. As shown in FIG. 2, the embodiment shown in FIG. 2 is an improvement of FIG. 1. The guide rail 170 includes at least two guide rail splicing pieces 171, and the at least two guide rail splicing pieces 171 are spliced end to end to form the guide rail 170.

The difference between this embodiment and the embodiment shown in FIG. 1 is that the guide rail 170 of this embodiment is formed by splicing at least two guide rail splicing pieces 171, and of the two guide rail splicing pieces 171 that are spliced to each other, one of the guide rail splicing pieces 171 may have an I-shaped structure, and the other guide rail splicing piece 171 may have a cross-shaped structure. The protruding piece of the guide rail splicing piece 171 of the cross-shaped structure in the horizontal direction may be embedded into the respective recessed part of the guide rail splicing piece 171 of the I-shaped structure in the horizontal direction, and finally the two splicing pieces are spliced into a complete track. Of course, the shape of the two mutually spliced guide rail splicing pieces 171 may also be other structures. When multiple guide rail splicing pieces 171 are spliced together, a combination of multiple guide rail splicing pieces 171 of different shapes may also be used to splice together to form the guide rail 170. For example, the middle part of the guide rail 170 may be mainly made up of a guide rail splicing piece 171 with an I-shaped structure and a guide rail splicing piece 171 with a cross-shaped structure, while the two ends of the guide rail 170 may be spliced using guide rail splicing pieces 171 with a U-shaped structure. This application does not specifically limit the shapes of the guide rail splicing pieces 171, and merely takes the guide rail splicing piece 171 with an I-shaped structure and the guide rail splicing piece 171 with a cross structure as an example.

Since the guide rail 170 in this embodiment adopts a modular design that is spliced by multiple guide rail splicing pieces 171, the length of the guide rail 170 can be lengthened or shortened by any combination of the multiple guide rail splicing pieces 171. When the width of the flexible cable 400 is relatively wide, a relatively larger number of guide rail splicing pieces 171 may be used for splicing to extend the length of the guide rail 170 so that the pressing device 120 and the second positioning piece 112 can have sufficient moving paths to press the relatively wide flexible cable 400 in cooperation. When the width of the flexible cable 400 is relatively narrow, the number of guide rail splicing pieces 171 may be reduced to shorten the length of the guide rail 170 so that the pressing device 120 and the second positioning piece 112 may have sufficient moving paths for cooperatively pressing the relatively narrow flexible cable 400 while reducing the space occupied by the pressing mechanism 100.

FIG. 3 is a schematic diagram of a third embodiment of the pressing mechanism according to the present application. As shown in FIG. 3, the embodiment shown in FIG. 3 is an improvement based on FIG. 2. The guide rail 170 includes a first guide rail 172 and a second guide rail 173. The first guide rail 172 is connected to the tops of the first positioning piece 111 and the second positioning piece 112. The second guide rail 173 is disposed below the first guide rail 172, and there is a gap between the first guide rail 172 and the second guide rail 173. The pressing device 120 is sleeved on the first guide rail 172. One end of the second guide rail 173 is connected to the side of the first positioning piece 111 facing towards the pressing device 120, and the other end passes through the second positioning piece 112 and is movably connected with the second positioning piece 112.

Different from the previous embodiment, this embodiment uses two guide rails 170 to respectively carry the pressing device 120 and the second positioning piece 112. The pressing device 120 is sleeved on the first guide rail 172, and the second positioning piece 112 is sleeved on the second guide rail 173. The pressing device 120 and the second positioning piece 112 can be flexibly adjusted in position on their respective guide rails 170, which allows for flexible adjustments and adaptations depending on the widths of the flexible cables 400 of more different specifications. Furthermore, the two different guide rails 170 share the stress of the pressing device 120 and the second positioning piece 112, so that the guide rails 170 are not prone to bending and deformation, further improving the structural stability and service life of the pressing device.

Of course, in order to prevent the guide rails 170 from bending or partially falling due to excessively long splicing lengths, the present application may further set fixing sleeves 191 on the first guide rail 172 and the second guide rail 173 respectively thus enhancing the structural stability of the first guide rail 172 and the second guide rail 173 through the fixing sleeves 191.

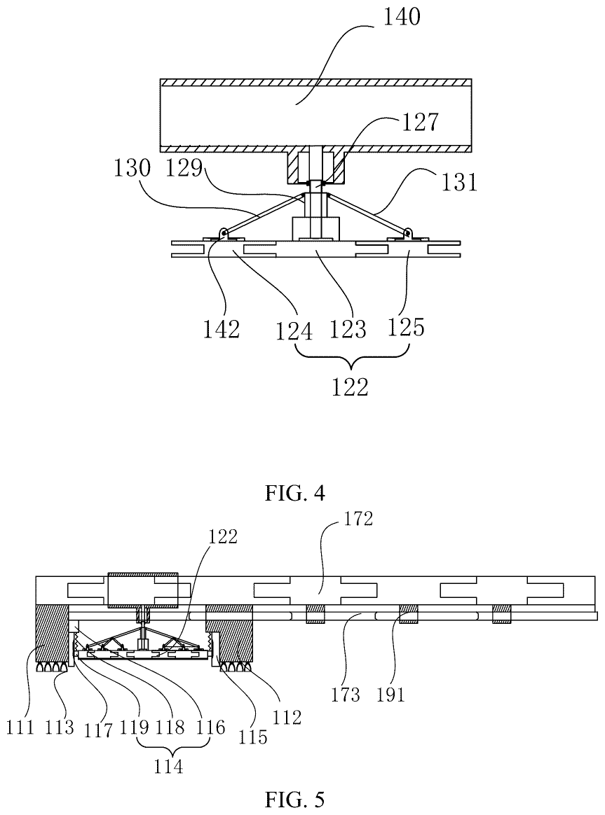

FIG. 4 is a schematic diagram of a fourth embodiment of the pressing mechanism of the present application. As shown in FIG. 4, the pressing head 122 includes a main pressing head splicing piece 123, a first pressing head splicing piece 124, and a second pressing head splicing piece 125. The main pressing head splicing piece 123 is connected to a side of the pressing head rod 127 facing towards the printed circuit board 300. The first pressing head splicing piece 124 and the second pressing head splicing piece 125 are respectively arranged on both sides of the main pressing head splicing piece 123. The first pressing head splicing piece 124, the main pressing head splicing piece 123, and the second pressing head splicing piece 125 are spliced end to end in order to form the pressing head 122. The first pressing head splicing piece 124 and the second pressing head splicing piece 125 each includes a connecting piece 142 on a side facing towards the guide rail 170. The pressing head assembly 121 further includes at least a first support rod 130 and a second support rod 131. One end of the first support rod 130 and one end of the second support rod 131 are detachably connected to both sides of the limiting sleeve 129, respectively. The other end of the first support rod 130 is detachably connected to the connecting piece 142 of the first pressing head splicing piece 124. The other end of the second support rod 131 is detachably connected to the connecting piece 142 of the second pressing head splice 125.

The difference between this embodiment and the previous embodiment is that the pressing head 122 in this embodiment uses multiple components to be spliced to form a modular pressing head 122. That is, it is formed by at least the main pressing head splicing piece 123, the first pressing head splicing piece 124, and the second pressing head splicing piece 125 being spliced end to end with each other. The main pressing head splicing piece 123 may be a cross-shaped structure, and the first pressing head splicing piece 124 and the second pressing head splicing piece 125 may each be an I-shaped structure. The protruding pieces on both sides of the main pressing head splicing piece 123 of the cross-shaped structure in the horizontal direction are respectively embedded into the recessed portions in the horizontal direction of the first pressing head splicing piece 124 and the second pressing head splicing piece 125 of the I-shaped structure. Finally, the main pressing head splicing piece 123, the first pressing head splicing piece 124, and the second pressing head splicing piece 125 are spliced to each other to form a complete pressing head 122. Of course, the main pressing head splicing piece 123 may also be an I-shaped structure, and the first pressing head splicing piece 124 and the second pressing head splicing piece 125 may correspondingly be cross-shaped structures, and they are spliced using the same splicing method. Furthermore, when there are multiple splicing pieces, they may all be spliced in the same way. Of course, the shapes of the two mutually spliced guide rail splicing pieces 171 may also be other structures. For example, the splicing pieces used at both ends of the pressing head 122 may have a U-shaped structure for splicing. This application does not specifically limit the shapes of the splicing pieces of the pressing head. It only takes the splicing pieces of I-shaped structure and cross-shaped structure to form the pressing head 122 as an example.

Since the pressing head 122 in this embodiment adopts a modular design that is spliced by multiple splicing pieces, the width of the pressing head 122 may be lengthened or shortened by any combination of multiple splicing pieces. When the width of the flexible cable 400 is relatively wide, a relatively larger number of splicing pieces may be used for splicing to extend the width of the pressing head 122 so that the pressing head 122 has a relatively larger pressing range, which can meet the need to press the relatively wider flexible cable 400. When the width of the flexible cable 400 is relatively narrow, the number of splicing pieces may be reduced to shorten the width of the pressing head 122 so that the pressing head 122 has an adaptable pressing range while the space occupied by the pressing head 122 can be reduced at the same time.

In addition, in order to increase the structural stability of the modular pressing head 122, prevent various parts of the pressing head 122 from falling off, and increase the structural strength of the pressing head 122, the main pressing head splicing piece 123 in this embodiment is directly connected to the pressing head rod 127, which may be an integrally formed design, so that the main pressing head splicing piece 123 has relatively strong structural stability and is not prone to falling off or breaking. The first pressing head splicing piece 124 and the second pressing head splicing piece 125 are movably connected to the limiting sleeve 129 by using the first support rod 130 and the second support rod 131 respectively. Furthermore, the first pressing head splicing piece 124 and the second pressing head splicing piece 125 are respectively detachably connected to the first support rod 130 and the second support rod 131, which not only facilitates the assembly and disassembly of multiple splicing pieces, but also makes the overall structure of the modular pressing head 122 relatively more stable.

It should be noted that when the pressing head 122 is made up of multiple pressing head splicing pieces, in order to ensure the overall stability of the pressing head 122, the number of supporting rods required will also increase. For example, when there are disposed three pressing head splicing pieces on each of both sides of the main pressing head splicing piece 123, three support rods may be needed on each side to support the three pressing head splicing pieces. In this case, one end of each of the two relatively shorter support rods may be connected to a middle of the respectively longer outermost support rod. In this way, the lever principle can be effectively used to share the forces acted on the three support rods, thus enhancing the support effect of the support rods.

Furthermore, in order to prevent the edges of the flexible cable 400 from warping on the printed circuit board 300 before pressing the junction between the flexible cable 400 and the printed circuit board 300 thus causing the problem of pseudo connection of some pins after the flexible cable 400 and the printed circuit board 300 are pressed and affecting the stability of signal transmission, this application further improves the first positioning piece 111 and the second positioning piece 112, as follows.

FIG. 5 is a schematic diagram of a fifth embodiment of the pressing mechanism according to the present application. As shown in FIG. 5, the first positioning piece 111 includes a first pre-pressing piece 114 on a side facing towards the pressing head 122, and the second positioning piece 112 includes a second pre-pressing piece 115 on a side facing towards the pressing head 122. Both the second pre-pressing piece 115 and the first pre-pressing piece 114 each include a support block 116, an elastic piece 118, and a pre-pressing block 119. A limiting groove 117 is defined in a side of the support block 116 facing towards the pressing head 122. A direction of extension of the limiting groove 117 points to the printed circuit board 300. One end of the elastic piece 118 is connected to a side of a top portion of the support block 116 facing towards the printed circuit board 300, and the other end is connected to the pre-pressing block 119. The pre-pressing block 119 is partially embedded in the limiting groove 117 and is able to move along the direction of extension of the limiting groove 117. The support block 116 of the first pre-pressing piece 114 and the support block 116 of the second pre-pressing piece 115 respectively abut against both sides of the flexible cable 400 in the width direction. In the natural state of the pre-pressing block 119, the distance between a bottom surface of the pre-pressing block 119 and a bottom surface of the support block 116 is less than a thickness of the flexible cable 400. The distance between the support block 116 and the printed circuit board 300 is greater than a half of a height of each suction cup 113 in its natural state, and is less than or equal to the height of each suction cup 113 in its natural state.

In this embodiment, the first pre-pressing piece 114 and the second pre-pressing piece 115 are respectively disposed on the side of the first positioning piece 111 and the side of the second positioning piece 112 facing towards the pressing head 122. Before the pressing device 120 presses the junction between the flexible cable 400 and the printed circuit board 300, the first pre-pressing piece 114 and the second pre-pressing piece 115 are used to pre-press the edges of the flexible cable 400 from the horizontal and vertical directions of the flexible cable 400 so that the junction between the flexible cable 400 and the printed circuit board 300 becomes relatively flatter and less prone to warping. Then when being pressed by the pressing device 120, the pins connected between the flexible cable 400 and the printed circuit board 300 are less likely to have pseudo connections.

During the actual pre-pressing process, first the first positioning piece 111 and the second positioning piece 112 are respectively adsorbed and fixed to both sides of the flexible cable 400 in the width direction using the suction cups 113, and the support blocks 116 respectively abut against both sides of the flexible cable 400. Since the distance between the bottom surface of the pre-pressing block 119 and the bottom surface of the support block 116 is less than the thickness of the flexible cable 400 under the natural state of the pre-pressing block 119, when the pre-pressing block 119 contacts the flexible cable 400, it will be lifted up by the flexible cable 400. The elastic piece 118 may be a spring. When the pre-pressure block 119 is lifted upward, the spring will be pressed. The pressed spring may give a reverse downward force to the pre-pressing block 119 due to its own elasticity, so that the pre-pressing block 119 may be pressed on each of both sides of the flexible cable 400, that is, pre-pressing is achieved from the vertical direction of the flexible cable 400, so that both sides of the flexible cable 400 become relatively flat and are not prone to warping. Then when being pressed by the pressing device 120, the pins connected between the flexible cable 400 and the printed circuit board 300 are less likely to have pseudo connections.

Since the pre-pressing block 119 is partially embedded in the limiting groove 117, there may be no dislocation or rotation during the lifting or pressing process of the pre-pressing block 119, and it may only move along the direction of extension of the limiting groove 117, ensuring the stability of the preloading block 119 pre-pressing the flexible cable 400 from the vertical direction.

In order to avoid hard contact between the pressing head 122 of the pressing device 120 and the flexible cable 400 during the pressing process, causing the pressing head 122 to damage the port pins of the flexible cable 400 during the relatively large pressing process, this application further improves the structure of the pressing head 122, where the specific improvements are as follows.

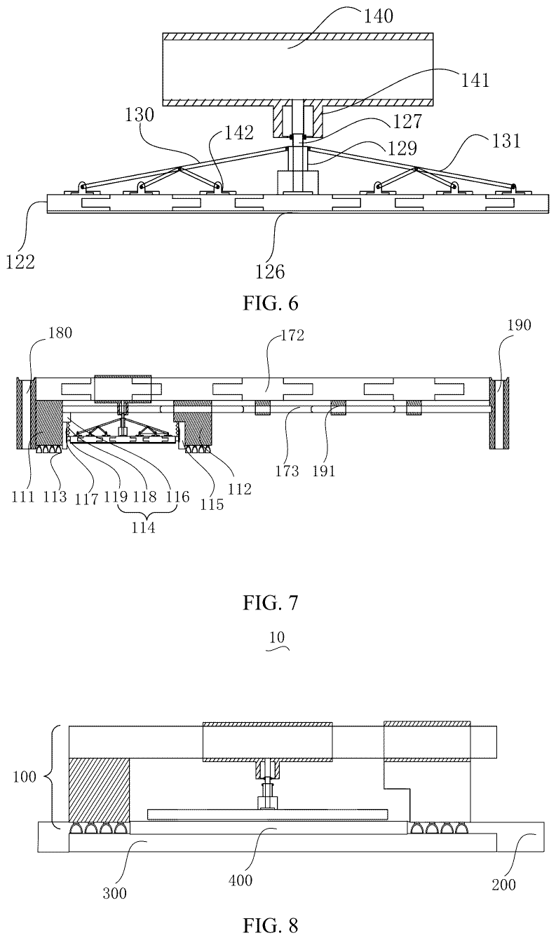

FIG. 6 is a schematic diagram of a sixth embodiment of the pressing mechanism according to the present application. As shown in FIG. 6, the embodiment shown in FIG. 6 is an improvement based on FIG. 5. A buffer layer 126 is disposed on the side of the pressing head 122 facing towards the printed circuit board 300. The buffer layer 126 is made of a plastic composite material.

The buffer layer 126 in this embodiment may be made of plastic composite materials such as rubber or resin. When the pressing head 122 of the pressing device 120 is pressing down, the buffer layer 126 disposed on the side of the pressing head 122 facing towards the printed circuit board 300 first makes a soft contact with the flexible cable 400, so that the pressing head 122 does not directly squeeze the flexible cable 400. Furthermore, during the process of the pressing head 122 being pressed down to a relatively large extent, the buffer layer 126 may also shrink to release the relatively large impact force caused by the pressing head 122 being pressed down, effectively preventing the pressing head 122 from causing damage to the port pins of the flexible cable 400, thereby further extending the service life of the flexible cable 400.

FIG. 7 is a schematic diagram of a seventh embodiment of the pressing mechanism according to the present application. As shown in FIG. 7, the embodiment shown in FIG. 7 is an improvement based on FIG. 6. The pressing mechanism 100 further includes a first support piece 180 and a second support piece 190. The first support piece 180 and the second support piece 190 are respectively connected to both sides of the guide rail 170. The distance separating the bottom surface of each of the first support piece 180 and the second support piece 190 from the printed circuit board 300 is greater than a half of the height of each suction cup 113 in its natural state.

Different from the previous embodiment, in this embodiment, the first support piece 180 and the second support piece 190 are arranged on both sides of the guide rail 170. The first support piece 180 and the second support piece 190 are used to support the guide rail 170 so that the guide rail 170 can withstand relatively greater force when the pressing head 122 of the pressing device 120 presses down. As such, in cases where the guide rail 170 is relatively long, it is not easy to bend and deform.

In the actual process of installing the first support piece 180 and the second support piece 190 to both sides of the guide rail 170, first screw holes may be opened in both sides of the guide rail 170, and second screw holes may be defined in the first support piece 180 and the second support piece 190 at positions corresponding to the first screw holes. Then the first screw hole and the second screw hole may be screwed together with screws, so that the first support piece 180 and the second support piece 190 are locked on both sides of the guide rail 170. Of course, a snap-connection may also be used. In particular, slots may be defined both sides of the guide rail 170, and protrusions may be disposed on the first support piece 180 and the second support piece 190 at positions corresponding to the slots, and so the protrusions may be snapped into the slots to complete the installation of the first support piece 180 and the second support piece 190 on the guide rail 170. This application does not specifically limit the connection method of connecting the first support piece 180 and the second support piece 190 to the guide rail 170. This embodiment merely takes the screw or snap junction between the first support piece 180 and second support piece 190 and the guide rail 170 as an example.

In addition, in order to avoid the installation of the first support piece 180 and the second support piece 190 from hindering the suction cups 113 of the first positioning piece 111 and the second positioning piece 112 by the first support piece 180 and the second support piece 190 when the suction cups 113 are adsorbed and fixed to the printed circuit board 300, causing the suction cups 113 to fail to reach a sufficient compression state thus affecting the adsorption capacity between the first positioning piece 111 and second positioning piece 112 and the printed circuit board 300, in this embodiment, the distance separating the bottom surface of each of the first support piece 180 and the second support piece 190 from the printed circuit board 300 is set to be greater than a half the height of each suction cup 113 in its natural state.

When the pressing mechanism 100 needs to be installed on the printed circuit board 300, first the first positioning piece 111 and the second positioning piece 112 are placed on the printed circuit board 300, and the first positioning piece 111 and the second positioning piece 112 are pressed down so that the suction cups 113 of the first positioning piece 111 and the second positioning piece 112 contract. When the suction cups 113 each shrink to more than half of the total height of the suction cup 113 in its natural state, there is sufficient suction force between the suction cup 113 and the printed circuit board 300 to enable the pressing device and the printed circuit board 300 to be stably connected together. When the suction cup 113 further contracts, the entire pressing mechanism 100 will move downward, and the first support piece 180 and the second support piece 190 located on both sides of the guide rail 170 will abut on the printed circuit board 300 to achieve support for the guide rail 170. At this time, when the pressing head 122 of the pressing device 120 is pressing down, the guide rail 170 can withstand a relatively greater force and is not prone to deformation, which improves the stability of the pressing mechanism 100 pressing the junction between the printed circuit board 300 and the flexible cable 400.

FIG. 8 is a schematic diagram of an embodiment of a display device according to the present application. As shown in FIG. 8, this application further discloses a display device 10, including a display panel 200. The display device 10 further includes the above-mentioned pressing mechanism 100, a printed circuit board 300, and a flexible cable 400. The printed circuit board 300 is connected to the display panel 200 through a flexible cable 400. The pressing mechanism 100 is disposed on the printed circuit board 300 and is used to press the junction between the flexible cable 400 and the printed circuit board 300.

The display device 10 of the present application may be a computer, a television, a monitor, or other equipment having a display function. The present application does not place any specific restrictions on the type of the display device 10.

In the display device 10, the display panel 200 may be required to display the screen content, but the display panel 200 itself is not capable of spontaneous display. A driving signal may need to be provided outside the display panel 200 through the printed circuit board 300. The printed circuit board 300 is connected to the display panel 200 through a flexible cable 400, and the stability of the junction between the printed circuit board 300 and the flexible cable 400 will directly affect the display effect, thereby affecting the quality of the display device 10.

In view of the above problems, this application improves the pressing mechanism 100 used for pressing the junction between the printed circuit board 300 and the flexible cable 400. The pressing mechanism 100 of the present application uses the pressing device 120 to press the junction between the printed circuit board 300 and the flexible cable 400, so that the flexible cable 400 and the printed circuit board 300 can be stably connected together and not easy to fall off, maintaining good signal transmission. The first positioning piece 111 and the second positioning piece 112 are used to press the flexible cable 400 from both sides in the width direction, so that the flexible cable 400 can be accurately positioned at the connection position with the printed circuit board 300, and positional deviation is not easy to occur, further improving the stability of the junction between the flexible cable 400 and the printed circuit board 300. The pressing device 120 and the second positioning piece 112 in this application can move along the guide rail 170, so that the positions of the pressing device 120 and the second positioning piece 112 can be adjusted together in cooperation depending on the width of the flexible cable 400 of different specifications so as to adjust the pressing range of the pressing mechanism 100, so that the first positioning piece 111 and the second positioning piece 112 can press against the flexible cables 400 of different widths. Furthermore, the pressing device 120 may be accurately aligned with and press the junction between the flexible cable 400 of different widths and the printed circuit board 300, so that the flexible cable 400 and the printed circuit board 300 may be stably connected together thus ensuring signal transmission and improving the applicability of the pressing mechanism 100. Furthermore, it is also convenient to replace the flexible cable 400, further extending the service life of the display device 10.

It should be noted that the inventive concept of the present application can be formed into many embodiments, but the length of the application document is limited and so these embodiments cannot be enumerated one by one. The technical features can be arbitrarily combined to form a new embodiment, and the original technical effect may be enhanced after the various embodiments or technical features are combined.

The foregoing description is merely a further detailed description of the present application made with reference to some specific illustrative embodiments, and the specific implementations of the present application will not be construed to be limited to these illustrative embodiments. For those having ordinary skill in the technical field to which this application pertains, numerous simple deductions or substitutions may be made without departing from the concept of this application, which shall all be regarded as falling in the scope of protection of this application.

What is claimed is:

1. A pressing mechanism, comprising:
a positioning device;
a pressing device; and
a guide rail;
wherein the positioning device is connected to a side of the guide rail facing towards a printed circuit board, wherein a direction of extension of the guide rail is consistent with a width direction of a flexible cable; wherein the pressing device is sleeved on the guide rail and is operative to move along the direction of extension of the guide rail; wherein the pressing device is used to press a junction between the printed circuit board and the flexible cable;
wherein the positioning device comprises a first positioning piece and a second positioning piece, which are respectively arranged on both sides of the pressing device; wherein the second positioning piece is movably connected to the guide rail and is operative to move along the direction of extension of the guide rail;
wherein the first positioning piece and the second positioning piece are detachably connected to the printed circuit board, and respectively abut against both sides of the flexible cable in the width direction.

2. The pressing mechanism as recited in claim 1, wherein the guide rail comprises at least two guide rail splicing pieces, wherein the at least two guide rail splicing pieces are spliced end to end to form the guide rail.

3. The pressing mechanism as recited in claim 2, wherein of every two guide rail splicing pieces that are spliced to each other, one of the two guide rail splicing pieces has an I-shaped structure, and the other guide rail splicing piece has a cross-shaped structure.

4. The pressing mechanism as recited in claim 3, wherein the guide rail splicing pieces disposed at both ends of the guide rail each have a U-shaped structure.

5. The pressing mechanism as recited in claim 2, wherein the guide rail comprises a first guide rail and a second guide rail, wherein the first guide rail is connected to a top of the first positioning piece and a top of the second positioning piece; wherein the second guide rail is disposed below the first guide rail, and there is defined a gap between the first guide rail and the second guide rail;
wherein the pressing device is sleeved on the first guide rail; wherein one end of the second guide rail is connected to a side of the first positioning piece facing towards the pressing device, and wherein another end of the second guide rail passes through the second positioning piece and is movably connected with the second positioning piece.

6. The pressing mechanism as recited in claim 2, wherein the pressing device comprises a pressing head assembly and a base, wherein the base is sleeved on the guide rail, wherein there is defined a storage cavity in a side of the base facing towards the printed circuit board, and wherein there is disposed in the storage cavity a first motor and a second motor that are spaced apart in a horizontal direction;
wherein the pressing head assembly comprises a pressing head, a pressing head rod, and a limiting sleeve; wherein one end of the pressing head rod passes through the limiting sleeve, is connected to the pressing head, and is partially exposed from the limiting sleeve; wherein a side of the limiting sleeve facing away from the base is connected to the pressing head;
wherein the pressing head rod is disposed between the first motor and the second motor; wherein the first motor comprises a first electric gear, the second motor comprises a second electric gear; wherein the part of the pressing head rod that is exposed from the limiting sleeve comprises a plurality of rack teeth disposed on side walls facing towards the first motor and the second motor, wherein the plurality of rack teeth are respectively connected to the first electric gear and the second electric gear, and wherein the first motor and the second motor are operative to rotate forward or reverse to control a rise or fall of the pressing head rod.

7. The pressing mechanism as recited in claim 6, wherein the limiting sleeve has a width that is greater than a distance between the first motor and the second motor, and wherein a height of a portion of the pressing head rod that is exposed from the limiting sleeve is equal to a thickness of the flexible cable.

8. The pressing mechanism as recited in claim 6, wherein the pressing head comprises a main pressing head splicing piece, a first pressing head splicing piece, and a second pressing head splicing piece; wherein the main pressing head splicing piece is connected to a side of the pressing head rod facing towards the printed circuit board; wherein the first pressing head splicing piece and the second pressing head splicing piece are respectively arranged on both sides of the main pressing head splicing piece; wherein the first pressing head splicing piece, the main pressing head splicing piece, and the second pressing head splicing piece are spliced end to end in sequence to form the pressing head; wherein the first pressing head splicing piece and the second pressing head splicing piece each comprise a connecting piece on a side facing towards the guide rail;
wherein the pressing head assembly further comprises at least a first support rod and a second support rod, wherein one end of the first support rod and one end of the second support rod are respectively movably connected to both sides of the limiting sleeve; wherein another end of the first support rod is movably connected to the connecting piece of the first pressing head splicing piece, and wherein another end of the second support rod is movably connected to the connecting piece of the second pressing head splicing piece.

9. The pressing device as recited in claim 8, wherein the main pressing head splicing piece is of a cross-shaped structure, and wherein the first pressing head splicing piece and the second pressing head splicing piece each have an I-shaped structure.

10. The pressing device as recited in claim 9, wherein the splicing pieces disposed at both ends of the pressing head have a U-shaped structure.

11. The pressing device as recited in claim 10, wherein the main pressing head splicing piece is connected to the pressing head rod and is integrally formed with the pressing head rod.

12. The pressing device as recited in claim 10, wherein the first pressing head splicing piece and the second pressing head splicing piece are respectively detachably connected to the first support rod and the second support rod.

13. The pressing mechanism as recited in claim 6, wherein the first positioning piece and the second positioning piece each comprise one or more suction cups disposed on a side facing towards the printed circuit board, wherein the first positioning piece and the second positioning piece are each suction-connected to the printed circuit board through the respective one or more suction cups.

14. The pressing mechanism as recited in claim 8, wherein a first pre-pressing piece is disposed on a side of the first positioning piece facing towards the pressing head, and a second pre-pressure piece is disposed on a side of the second positioning piece facing towards the pressing head;
wherein the second pre-pressing piece and the first pre-pressing piece each comprise a support block, an elastic piece, and a pre-pressing block, wherein a limiting groove is defined in a side of the support block facing towards the pressing head; wherein a direction of extension of the limiting groove is a direction in which the pressing head points to the printed circuit board; wherein one end of the elastic piece is connected to a side of a top of the support block facing towards the printed circuit board, and wherein another end of the elastic piece is connected to the pre-pressing block; wherein the pre-pressing block is partially embedded in the limiting groove and is operative to move along the direction of extension of the limiting groove;
wherein the support block of the first pre-pressing piece and the support block of the second pre-pressing piece respectively abut against both sides of the flexible cable in the width direction; wherein under a natural state of the pre-pressing block, a distance between a bottom surface of each pre-pressing block and a bottom surface of the respective support block is less than a thickness of the flexible cable; wherein a distance between each support block and the printed circuit board is greater than a half of a height of each suction cup and less than or equal to the height of each suction cup.

15. The pressing mechanism as recited in claim 14, further comprising a first support piece and a second support piece, which are respectively connected to both sides of the guide rail;
wherein a distance separating bottom surfaces of the first support piece and the second support piece from the printed circuit board is greater than half the height of each suction cup.

16. The pressing mechanism as recited in claim 15, wherein there are defined a first screw hole in each of both sides of the guide rail, wherein the first support piece and the second support piece each define a second screw hole corresponding to a position of the respective first screw hole, and wherein the corresponding first screw hole and second screw hole are screwed together through a screw.

17. The pressing mechanism as recited in claim 15, wherein the guide rail defines a slot in each of both sides, and wherein the first support piece and the second support piece each comprise a protrusion corresponding to a position of the respective slot, and wherein the protrusion is operative to be engaged with the respective slot.

18. The pressing mechanism as recited in claim 6, wherein a buffer layer is disposed on a side of the pressing head facing towards the printed circuit board, and wherein the buffer layer is made of a plastic composite material.

19. The pressing mechanism as recited in claim 18, wherein the buffer layer is made of a rubber or resin material.

20. A display device, comprising a display panel, wherein the display device further comprises a pressing mechanism, a printed circuit board, and a flexible cable; wherein the printed circuit board is connected to the display panel through the flexible cable, and the pressing mechanism is disposed on the printed circuit board and is used to press a junction between the flexible cable and the printed circuit board; wherein the pressing mechanism comprises:
a positioning device;
a pressing device; and
a guide rail;
wherein the positioning device is connected to a side of the guide rail facing towards a printed circuit board, wherein a direction of extension of the guide rail is consistent with a width direction of a flexible cable; wherein the pressing device is sleeved on the guide rail and is operative to move along the direction of extension of the guide rail; wherein the pressing device is used to press a junction between the printed circuit board and the flexible cable;
wherein the positioning device comprises a first positioning piece and a second positioning piece, which are respectively arranged on both sides of the pressing device; wherein the second positioning device is movably connected to the guide rail and is operative to move along the direction of extension of the guide rail;
wherein the first positioning piece and the second positioning piece are detachably connected to the printed circuit board, and respectively abut against both sides of the flexible cable in the width direction.
